(19) United States
(12) Patent Application Publication
(10) Pub. No.: US 2014/0158178 A1
(43) Pub. Date: Jun. 12, 2014

(54) THERMOELECTRIC GENERATOR AND THERMOELECTRIC GENERATING SYSTEM

(71) Applicant: INDUSTRIAL TECHNOLOGY RESEARCH INSTITUTE, (US)

(72) Inventors: Cheng-Chou Wong, Hsinchu County (TW); Jenn-Dong Hwang, Hsinchu City (TW); Cheng-Ting Hsu, Hsinchu City (TW); Hsu-Shen Chu, Hsinchu City (TW)

(73) Assignee: INDUSTRIAL TECHNOLOGY RESEARCH INSTITUTE, Hsinchu (TW)

(21) Appl. No.: 13/832,068

(22) Filed: Mar. 15, 2013

(30) Foreign Application Priority Data
Dec. 10, 2012 (TW) 101146421

(51) Int. Cl. H01L 35/30

(52) U.S. Cl. CPC H01L 35/30
USPC 136/205

(57) ABSTRACT

A thermoelectric generator (TEG) including a cooling element, a heat-collection element and at least one thermoelectric generating module is provided. The heat-collection element is disposed at a side of the cooling element, wherein the heat-collection element has a first surface and a second surface opposite to the first surface, and the heat-collection element is suitable for facing a thermal radiation source with the first surface so as to receive thermal energy thereof in a predetermined distance without contacting the thermal radiation source. The thermoelectric generating module is disposed between the second surface of the heat-collection element and the cooling element, wherein the emissivity of the heat-collection element is larger than 0.8. A thermoelectric generating system is also provided.

### CROSS-REFERENCE TO RELATED APPLICATION

This application claims the priority benefit of Taiwan application serial no. 101146421, filed on Dec. 10, 2012. The entirety of the above-mentioned patent application is hereby incorporated by reference herein and made a part of this specification.

### TECHNICAL FIELD

The technical field relates to a thermoelectric generator (TEG) and a thermoelectric generating system.

### BACKGROUND

Recently, as the industry develops and prospers, the industrial apparatuses such as kilns or combustion apparatuses, etc., which generate great amount of waste heat due to operation are used more and more frequently, and the thermal energy generated by the industrial apparatuses would be dissipated to the surrounding environment and causes thermal pollution. Due to drastic variation of environmental climate and shortage of energy, the consciousness of environmental protection gradually raises and the related issue has become a dominant concern for the industry. Therefore, all kinds of related solutions have been developed accordingly, and thermoelectric generation is one of them.

Thermoelectric generator (TEG) is an apparatus for converting thermal energy into electric energy, which uses thermoelectric generating modules composed of thermoelectric material made from semiconductor material to perform thermoelectric conversion through the temperature difference between a heat-collection element and a cooling element. Therefore, the thermoelectric generator is capable of converting the waste heat into electric energy by recycling the waste heat described above. This can reduce the damage to the environment caused by industry waste heat, and can develop a new source for the energy which gradually decreases, so as to achieve the effect of environmental protection such as energy saving, carbon reduction, heat reduction and electricity generation, etc.

### SUMMARY

One of exemplary embodiments includes a thermoelectric generator (TEG). The TEG at least includes a cooling element, a heat-collection element, and at least one thermoelectric generating module. The heat-collection element is disposed at one side of the cooling element, wherein the heat-collection element has a first surface and a second surface opposite to the first surface, and the heat-collection element is suitable for facing a thermal radiation source with the first surface so as to receive thermal energy of the thermal radiation source in a predetermined distance without contacting the thermal radiation source. The thermoelectric generating module is disposed between the second surface of the heat-collection element and the cooling element, wherein the emissivity of the heat-collection element is larger than 0.8.

One of exemplary embodiments includes a thermoelectric generating system. The thermoelectric generating system at least includes a thermal radiation source and a thermoelectric generator (TEG). The TEG is disposed at one side of the thermal radiation source for generating electricity by receiving thermal energy of the thermal radiation source. The TEG includes a cooling element, a heat-collection element, and at least one thermoelectric generating module. The heat-collection element is disposed at one side of the cooling element, wherein the heat-collection element has a first surface and a second surface opposite to the first surface, and the heat-collection element faces the thermal radiation source with the first surface so as to receive thermal energy of the thermal radiation source in a predetermined distance without contacting the thermal radiation source. The thermoelectric generating module is disposed between the second surface of the heat-collection element and the cooling element, wherein the emissivity of the heat-collection element is larger than 0.8.

In order to make the aforementioned features of the disclosure more comprehensible, embodiments accompanied with figures are described in details below.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic view of a thermoelectric generating system according to an embodiment.

FIG. 2 is a schematic view of the thermoelectric generator (TEG) of FIG. 1.

FIG. 3 is a schematic view of the thermoelectric generating module of FIG. 2.

FIG. 4 is a schematic view of the thermoelectric generator (TEG) according to another embodiment.

FIG. 5 is a schematic view of a thermoelectric generating system according to another embodiment.

FIG. 6 is a schematic view of the thermoelectric generator (TEG) of FIG. 5.

FIG. 7 is a schematic view of the heat-collection element of FIG. 6.

FIG. 8 is a schematic view of a heat-collection element according to yet another embodiment.

FIG. 9 is a schematic view of a heat-collection element according to still another embodiment.

FIG. 10 is a schematic view of a heat-collection element according to still another embodiment.

FIG. 11 is a flow chart illustrating the heat-collection method of thermoelectric generating system of FIG. 1.

### DESCRIPTION OF EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

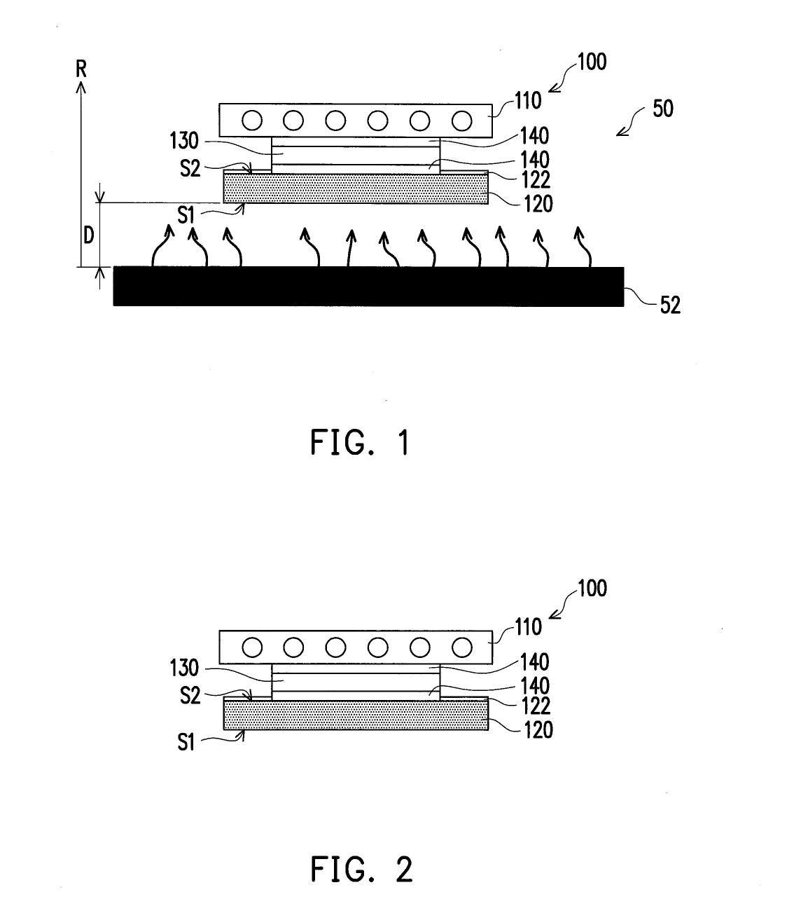

FIG. 1 is a schematic view of a thermoelectric generating system according to an embodiment. FIG. 2 is a schematic view of the thermoelectric generator (TEG) of FIG. 1. Referring to FIG. 1 and FIG. 2, in the present embodiment, a thermoelectric generating system 50 includes a thermal radiation source 52 and a thermoelectric generator (TEG) 100. The thermal radiation source 52 is the apparatus such as kiln or combustion apparatus, etc., which generates thermal energy due to operation, and the thermal energy thereof is dissipated to the outside of the apparatus by thermal radiation, but the disclosure does not limit the types and the formations of the thermal radiation source 52. The thermoelectric generator (TEG) 100 is disposed at one side of the thermal radiation source 52 for generating electricity by receiving thermal energy of the thermal radiation source 52.

In the present embodiment, the TEG 100 includes a cooling element 110, a heat-collection element 120, at least one thermoelectric generating module 130 and two interface elements 140. The cooling element 110 is, for example, an air-cooling system or a water-cooling system. The heat-collection element 120 may be manufactured by the manufacturing processes such as extrusion, diecasting, stamping, forging, bending or metal injection molding, etc. The heat-collection element 120 is disposed at one side of the cooling element 110, wherein the heat-collection element 120 has a first surface S1 and a second surface S2 opposite to the first surface S1, and the heat-collection element 120 faces the thermal radiation source 52 with the first surface S1 so as to receive thermal energy of the thermal radiation source 52 in a predetermined distance D without contacting the thermal radiation source 52. Therefore, the temperature of the heat-collection element 120 is higher than the temperature of the cooling element 110, such that there is a temperature difference between these two.

On the other hand, in the present embodiment, the thermoelectric generating module 130 is disposed between the second surface S2 of the heat-collection element 120 and the cooling element 110 and connects the cooling element 110 and the heat-collection element 120, so as to generate electricity through the temperature difference between the cooling element 110 and the heat-collection element 120. The two interface elements 140 are respectively disposed between the heat-generating module 130 and the heat-collection element 120 and between the heat-generating module 130 and the cooling element 110. The material of the interface elements 140 is, for example, the material with high thermal conductivity such as thermal conductive paste, thermal conductive gel or graphite film, etc., so as to enhance the efficiency of the cooling element 110 and the heat-collection element 120 transmitting heat to the thermoelectric generating module 130. However, the disclosure does not limit the material or the types of the cooling element 110, heat-collection element 120 and the interface elements 140. Any material or element having similar functions may be applied to the disclosure.

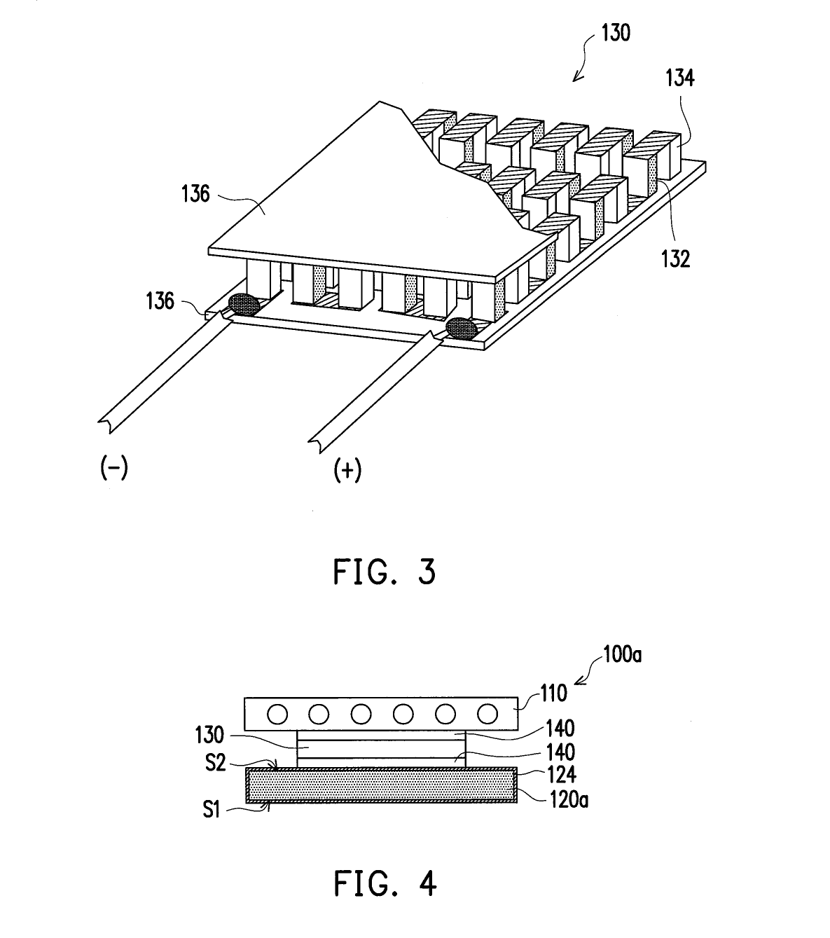

FIG. 3 is a schematic view of the thermoelectric generating module of FIG. 2. Referring to FIG. 1 and FIG. 3, in the present embodiment, the thermoelectric generating module 130 includes a plurality of P-type thermoelectric elements 132 and a plurality of N-type thermoelectric elements 134. The P-type thermoelectric elements 132 and N-type thermoelectric elements 134 are connected in series and fixed between two substrates 136 (a cold terminal substrate and a hot terminal substrate) by solder (not shown), such that the thermoelectric generating module 130 transmits the temperature difference between the cooling element 110 and the heat-collection element 120 by the substrates 136 and generates electricity through the P-type thermoelectric elements 132 and the N-type thermoelectric elements 134. In addition, in other embodiments, the TEG may include a plurality of thermoelectric generating modules 130. The thermoelectric generating modules 130 are connected in series or in parallel, and are disposed between the second surface S2 of the heat-collection element 120 and the cooling element 110. The thermoelectric generating modules 130 connect the cooling element 110 and the heat-collection element 120, but the disclosure does not limit the amount of the thermoelectric generating modules 130.

Moreover, in the present embodiment, the part of the second surface S2 of the heat-collection element 120 not contacting the thermoelectric generating module 130 has a thermal insulating coating 122. Therefore, after the first surface S1 of the heat-collection element 120 faces the thermal radiation source 52 and receives the thermal energy of the thermal radiation source 52, the thermal energy may be directly transmitted to the thermoelectric generating module 130 from the part of the second surface S2 of the heat-collection element 120 contacting the thermoelectric generating module 130, and is not transmitted to external environment from the part of the second surface S2 of the heat-collection element 120 not contacting the thermoelectric generating module 130, so as to ensure the temperature difference between the thermal energy transmitted from the heat-collection element 120 to the thermoelectric generating module 130 and the cooling element 110 is great enough for the thermoelectric generating module 130 to have satisfactory effect of electricity generation.

On the other hand, by selecting the heat-collection element 120 made of the material with high emissivity, high thermal conductivity and high specific surface area, the thermal energy radiated from the thermal radiation source 52 may be effectively collected within a predetermined distance D, and the temperature difference between the cooling element 110 and the heat-collection element may increase so as to enhance the electricity generation efficiency of the thermoelectric generating module 130. The material with high emissivity, high thermal conductivity and high specific surface area is, for example, the material with high emissivity due to the black appearance thereof, or the material with rough surface (high specific surface area) so as to receive thermal energy easily, or the material with high thermal conductivity, hard to reflect the received thermal energy and easy to transmit the thermal energy to the thermoelectric generating module 130. Therefore, the material of the cooling element 120 may be porous material or carbon-containing composite material, or a black anodic aluminum oxide process may be performed on the surface of the cooling element 120, or a coating having the property described above is coated on the cooling element 120, such that the coefficient of thermal radiation of the cooling element 120 is greater than 0.8 to effectively receive the thermal energy.

In the present embodiment, the material of the heat-collection element 120 is porous material such as carbon foam. The specific surface area of the carbon foam is greater than 2000 m²/m³, the thermal conductivity is greater than 1000 W/mK, and the emissivity is about 0.9. Therefore, the carbon foam has all the properties of high emissivity, high thermal conductivity and high specific surface area, such that the thermal energy radiated from the thermal radiation source 52 may be effectively collected within the predetermined distance D, and the thermal energy is transmitted to the thermoelectric generating module 130 quickly so as to enhance the electricity generation efficiency of the thermoelectric generating module 130. However, in other embodiment, the material of the heat-collection element 120 may be carbon-containing composite material such as carbon fiber aluminum-based composite material, carbon fiber copper-based composite material, graphite aluminum-based composite material or graphite copper-based composite material. For example, the thermal conductivity of graphite aluminum-based composite material is from 200 W/mK to 600 W/mK, and the emissivity is about 0.85, which enables the heat-collection element 120 to collect the thermal energy of the thermal radiation source 52 effectively, and transmit the thermal energy quickly to the thermoelectric generating module 130, but the disclosure is not limited thereto.

In the present embodiment, the thermal radiation source 52 may have an uneven surface or is a rotational thermal radiation source such as a rotational industrial kiln. Therefore, a common contact-type (attaching type) TEG can not transmit the thermal energy directly to the TEG by contacting the external wall of this type of apparatus. However, the heat-collection element 120 of the present embodiment is suitable for facing the thermal radiation source 52 with the first surface S1 thereof, so as to receive the thermal energy of the thermal radiation source 52 within the predetermined distance D without contacting the thermal radiation source 52, and the thermoelectric generating module 130 generates electricity through the temperature difference between the cooling element 110 and the heat-collection element 120. Thus, as long as the heat-collection element 120 of the TEG 100 is disposed at one side of the thermal radiation source 52 and is separated from the thermal radiation source 52 by the predetermined distance D (the predetermined distance D is usually from several centimeters to decades of centimeters), the thermal energy of the thermal radiation source 52 can be effectively collected. Accordingly, the TEG 100 and the thermoelectric generating system 50 of the disclosure have satisfactory effect of heat collection and electricity generation.

FIG. 4 is a schematic view of the thermoelectric generator (TEG) according to another embodiment. Referring to FIG. 4, in the present embodiment, the main difference between the TEG 100a and the TEG 100 is that the heat-collection element 120a of the TEG 100a has a thermal conductive layer 124. The thermal conductive layer 124 is disposed on the surface of the heat-collection element 120a, so as to enhance the emissivity of the heat-collection element 120a. To be more specific, the material of the heat-collection element 120a may be porous material such as metal foam, wherein the metal foam may be aluminum foam or copper foam, but the disclosure is not limited thereto. This type of metal foam has high specific surface area and high thermal conductivity due to the porous and metallic properties thereof, but the emissivity thereof is not as satisfactory as that of the carbon foam and carbon-containing composite material described above. Therefore, the heat-collection element 120a made of this type of metal foam may enhance the emissivity thereof by disposing the thermal conductive layer 124, for example, a black anodic aluminum oxide processed layer disposed on the surface of the heat-collection element 120a by performing a black anodic aluminum oxide process, such that the appearance of the heat-collection element 120a represents black color so as to enhance the emissivity of the heat-collection element 120a.

On the other hand, the material of the heat-collection element 120a may also be metal such as aluminum or copper. The heat-collection element 120a made of this type of metal may also enhance the emissivity of the heat-collection element 120a by disposing the thermal conductive layer 124 on the surface through the black anodic aluminum oxide process. In addition, the heat-collection element 120a made of this kind of metal may also enhance the emissivity by disposing a thermal conductive layer 124, for example, a spray coating layer disposed on the cooling element 120a by spray coating a material with high emissivity (the emissivity is greater than 0.7), but the disclosure does not limit the material of the heat-collection element 120a and the thermal conductive layer 124, and the disposing method of the thermal conductive layer 124.

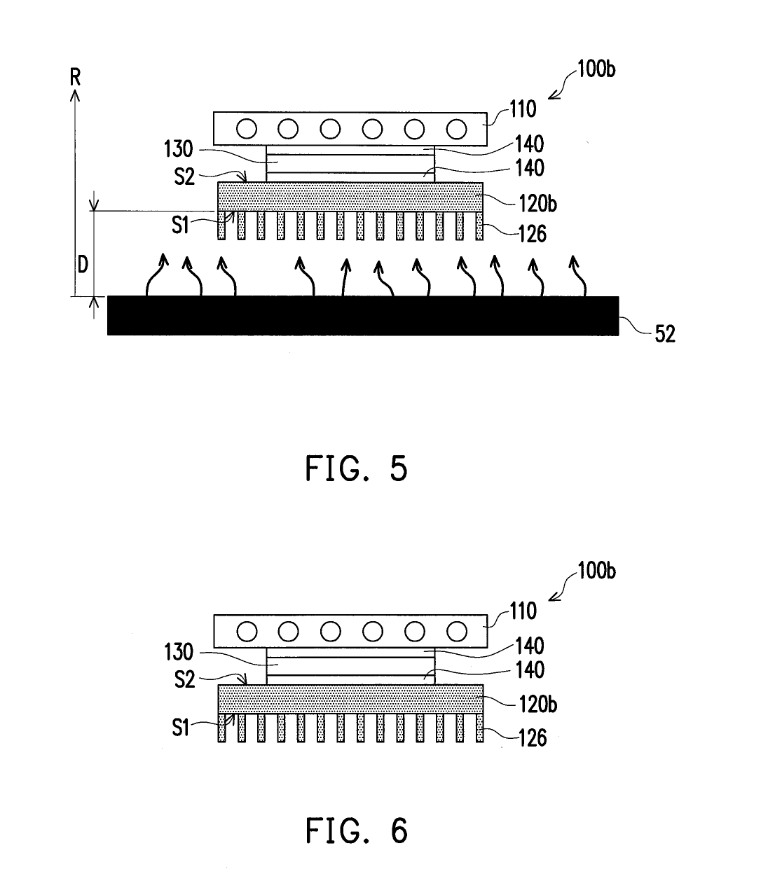

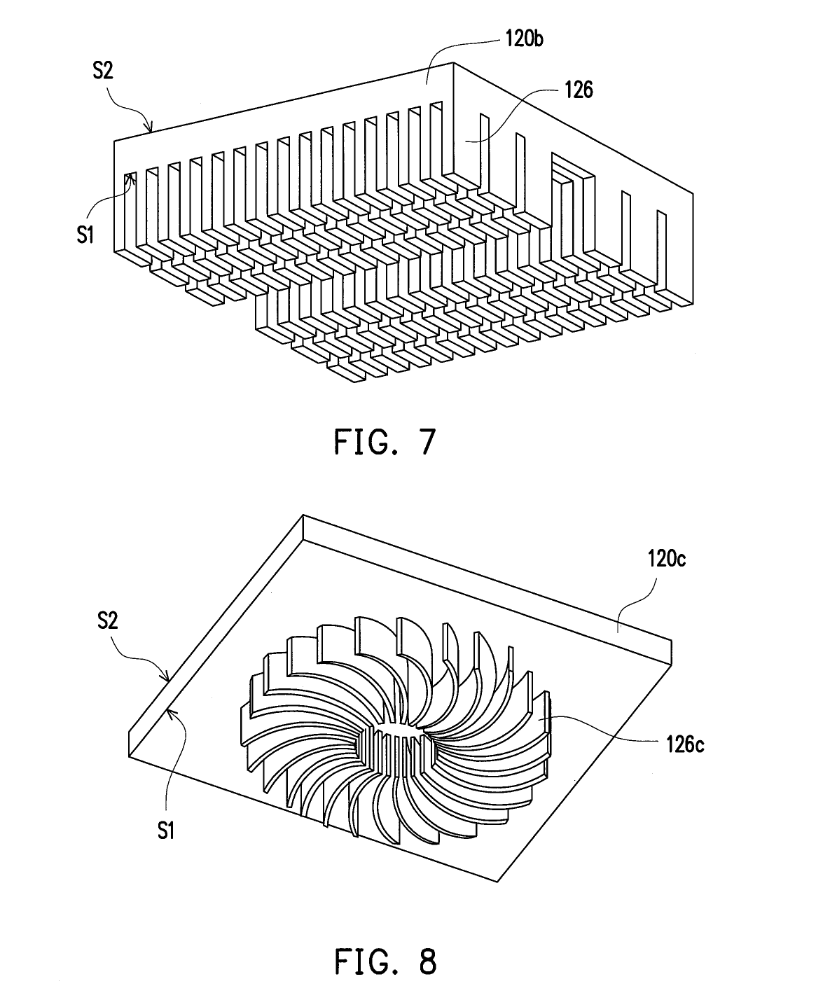

FIG. 5 is a schematic view of a thermoelectric generating system according to another embodiment. FIG. 6 is a schematic view of the thermoelectric generator (TEG) of FIG. 5. FIG. 7 is a schematic view of the heat-collection element of FIG. 6. Referring to FIG. 5 to FIG. 7, in the present embodiment, the main difference between the TEG 100b and the TEG 100 is that the heat-collection element 120b of the TEG 100b has a plurality of heat-collection fins 126. The heat-collection fins 126 located at the first surface S1 of the heat-collection element 120b face the thermal radiation source 52 and receive the thermal energy from the thermal radiation source 52, wherein the heat-collection fins 126 are sheet structures and distributed all over the first surface S1 of the heat-collection element 120b, as shown in FIG. 7. Therefore, the heat-collection element 120b may increase the surface area thereof through the heat-collection fins 126, so as to enhance the thermal-energy receiving efficiency (thermal conductivity) of the heat-collection element 120b. In other embodiments, the shapes and the arrangements of the heat-collection fins of the heat-collection element may be adjusted according to the requirements. The disclosure is not limited thereto.

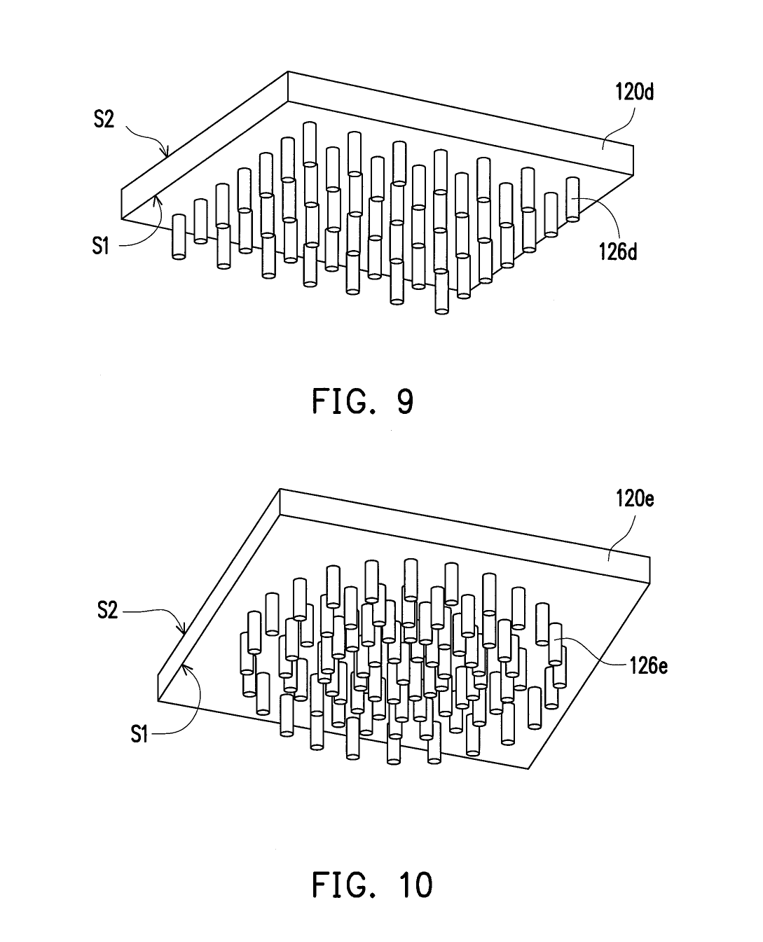

FIG. 8 is a schematic view of a heat-collection element according to still another embodiment. FIG. 9 is a schematic view of a heat-collection element according to still another embodiment. FIG. 10 is a schematic view of a heat-collection element according to still another embodiment. Referring to FIG. 8 to FIG. 10, in these embodiments, the heat-collection elements respectively have the heat-collection fins in different shapes and with different arrangements according to actual demands. In the embodiment of FIG. 8, the heat-collection fins 126c of the heat-collection element 120c are sheet structures in arc shapes, and the heat-collection fins 126c are in radial arrangement located on the center of the first surface S1 of the heat-collection element 120c. In the embodiment of FIG. 9, the heat-collection fins 126d of the heat-collection element 120d are cylindrical structures, and the heat-collection fins 126d are distributed all over the first surface S1 of the heat-collection element 120d. In the embodiment of FIG. 10, the heat-collection fins 126e of the heat-collection element 120e are cylindrical structures, and the heat-collection fins 126e are in circular arrangement located on the center of the first surface S1 of the heat-collection element 120e. According to the foregoing embodiments, the shapes and the arrangements of the heat-collection fins of the TEG may be adjusted according to actual demands, such that the TEG has satisfactory effect of heat collection and electricity generation.

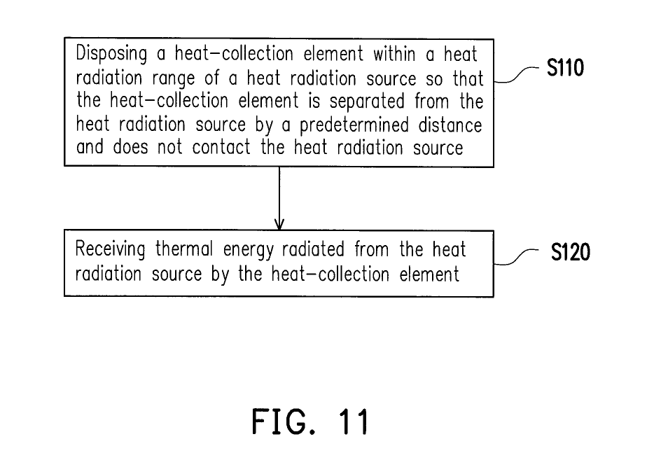

FIG. 11 is a flow chart illustrating the heat-collection method of thermoelectric generating system of FIG. 1. Referring to FIG. 1 and FIG. 11, in the present embodiment, the heat-collection method is suitable for the heat-collection element 120 of the TEG 100 to collect the thermal energy of the thermal radiation source 52. The heat-collection method includes the following steps. In the step S110, a heat-collection element 120 is disposed within a thermal radiation range R of a thermal radiation source and the heat-collection element 120 is separated from the thermal radiation source 52 by a predetermined distance D and does not contact the thermal radiation source 52. In the step S120, thermal energy radiated from the thermal radiation source 52 is received by the heat-collection element 120.

To be more specific, the thermal radiation source 52 may have different thermal radiation range R according to the type and the operation condition thereof. The heat-collection element 120 is disposed within the thermal radiation range R of the thermal radiation source 52 to ensure the heat-collection element 120 is capable of receiving the thermal radiation source 52. In addition, the thermal radiation source 52 has an uneven surface or is a rotational thermal radiation source. The heat-collection element 120 is disposed at one side of the thermal radiation source 52, and is separated from the thermal radiation source 52 by the predetermined distance D without contacting the thermal radiation source 52, wherein the predetermined distance D may be adjusted according to actual demands, so as to receive the thermal energy under the circumstance of not affecting the operation of the thermal radiation source 52. Therefore, the heat-collection element 120 is capable of receiving the thermal energy radiated from the thermal radiation source 52 and transmitting the thermal energy to the thermoelectric generating module 130 of the TEG 100, such that the thermoelectric generating module 130 generates electricity through the temperature difference between the cooling element 110 and the heat-collection element 120. In addition, in other embodiments, the heat-collection element 120b has heat-collection fins 126, as shown in FIG. 5. Therefore, the heat-collection element 120b may receive the thermal energy radiated from the thermal radiation source 52 by facing the heat-collection fins 126 to the thermal radiation source 52. Accordingly, the heat-collection method of the disclosure has satisfactory effect of heat collection.

Upon conducting actual measurements on the TEGs in different embodiments, wherein the thermal radiation source 52 is rotational industrial kiln, and the temperature of the external wall of the kiln is about 300° C. to 320° C., and the TEG is separated from the thermal radiation source 52 by the predetermined distance D (about 10 centimeters to 20 centimeters) without contacting the thermal radiation source 52. Under the conditions described above, for the heat-collection element which the material thereof is carbon-containing composite material and has heat-collection fins, the temperature of the hot terminal of the thermoelectric generating module connected to the heat-collection element is 110° C., and the power of the electricity generation of the TEG is 7.5 W. For the heat-collection element which the material thereof is aluminum, the black anodic aluminum oxide process is performed on the surface thereof and has heat-collection fins, the temperature of the hot terminal of the thermoelectric generating module connected to the heat-collection element is 90° C., and the power of the electricity generation of the TEG is 5.5 W. For the heat-collection element which the material thereof is aluminum, the black anodic aluminum oxide process is not performed on the surface thereof and does not have heat-collection fins, the temperature of the hot terminal of the thermoelectric generating module connected to the heat-collection element is 80° C., and the power of the electricity generation of the TEG is 3.7 W. Therefore, by choosing the material with high emissivity, high thermal conductivity and high specific surface area as the material of the heat-collection element, or by choosing to dispose heat-collection fins on the heat-collection element, the TEG and the thermoelectric generating system are capable of having satisfactory effect of heat collection and electricity generation.

Based on the above, in the TEG and the thermoelectric generating system of the disclosure, the heat-collection element faces the thermal radiation source, so as to receive the thermal energy of the thermal radiation source in the predetermined distance without contacting the thermal radiation source, wherein the material of the heat-collection element is the material with high emissivity, high thermal conductivity and high specific surface area, such that the thermal-energy receiving efficiency of the heat-collection element is enhanced. The thermoelectric generating module is disposed between the heat-collection element and the cooling element, so as to generate electricity through the temperature difference between the cooling element and the heat-collection element. Accordingly, the TEG and the thermoelectric generating system of the disclosure have satisfactory effect of heat collection and electricity generation. In addition, in the heat-collection method of the disclosure, the heat-collection element is disposed within the thermal radiation range of the thermal radiation source, so as to receive the thermal energy of the thermal radiation source within the predetermined distance without contacting the thermal radiation source. Accordingly, the heat-collection method of the disclosure has satisfactory effect of heat collection.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A thermoelectric generator (TEG), comprising:
a cooling element;
a heat-collection element, disposed at one side of the cooling element, wherein the heat-collection element has a first surface and a second surface opposite to the first surface, and the heat-collection element is suitable for facing a thermal radiation source with the first surface so as to receive thermal energy of the thermal radiation source in a predetermined distance without contacting the thermal radiation source; and
at least one thermoelectric generating module, disposed between the second surface of the heat-collection element and the cooling element, wherein a emissivity of the heat-collection element is larger than 0.8.

2. The TEG as claimed in claim 1, wherein the material of the heat-collection element comprises porous material or carbon-containing composite material.

3. The TEG as claimed in claim 1, wherein the heat-collection element has a plurality of heat-collection fins, located at the first surface of the heat-collection element and suitable for facing the thermal radiation source and receiving the thermal energy of the thermal radiation source.

4. The TEG as claimed in claim 1, further comprising:
two interface elements, respectively disposed between the thermoelectric generating module and the heat-collection element, and between the thermoelectric generating module and the cooling element.

5. A thermoelectric generating system, comprising:
a thermal radiation source; and
a thermoelectric generator (TEG), disposed at one side of the thermal radiation source for generating electricity by receiving thermal energy of the thermal radiation source, the TEG comprising:
a cooling element;
a heat-collection element, disposed at one side of the cooling element, wherein the heat-collection element has a first surface and a second surface opposite to the first surface, and the heat-collection element faces the thermal radiation source with the first surface so as to receive thermal energy of the thermal radiation source in a predetermined distance without contacting the thermal radiation source; and
at least one thermoelectric generating module, disposed between the second surface of the heat-collection element and the cooling element, wherein a emissivity of the heat-collection element is larger than 0.8.

6. The thermoelectric generating system as claimed in claim 5, wherein the material of the heat-collection element comprises porous material or carbon-containing composite material.

7. The thermoelectric generating system as claimed in claim 5, wherein the heat-collection element has a plurality of heat-collection fins, located at the first surface of the heat-collection element and suitable for facing the thermal radiation source and receiving the thermal energy of the thermal radiation source.

8. The thermoelectric generating system as claimed in claim 5, wherein the TEG further comprising:
two interface elements, respectively disposed between the thermoelectric generating module and the heat-collection element, and between the thermoelectric generating module and the cooling element.

9. The thermoelectric generating system as claimed in claim 5, wherein the thermal radiation source has an uneven surface or is a rotational thermal radiation source.
